(19) United States
(12) Patent Application Publication
(10) Pub. No.: US 2026/0160796 A1
(43) Pub. Date: Jun. 11, 2026

(54) Method and Device for Automatically Detecting a Thermal Anomaly in Equipment

(71) Applicant: THALES, Meudon (FR)

(72) Inventors: Philippe DUBEDAT, Merignac (FR); Joseph RECROSIO, Merignac (FR); Marine DELLIS, Merignac (FR)

(21) Appl. No.: 19/408,666

(22) Filed: Dec. 4, 2025

(30) Foreign Application Priority Data
Dec. 6, 2024 (FR) FR24 13573

(51) Int. Cl. G01R 31/28; G01K 3/10

(52) U.S. Cl. CPC G01R 31/2817; G01K 3/10

(57) ABSTRACT

The present invention relates to a method for automatically detecting a thermal anomaly of equipment, including the steps of:

Calculating T_{eq}(t), towards which the temperature T(t) of the equipment tends in the vicinity of t, verifying, by local extrapolation of T(t) in an exponential form:

$$T ( t + Δ t ) = {T}_{e q} ( t ) + [ T ( t ) - {T}_{e q} ( t ) ] \cdot {e}^{- \frac{Δ t}{τ}}$$

predicting an asymptotic equilibrium temperature \hat{T}_{eq}(t), based on usage variables, characterizing the use and context of use of the equipment at instant t;
determining based on T_{eq}(t)−\hat{T}_{eq}(t) the presence of a thermal anomaly of the equipment.

### CROSS-REFERENCE TO RELATED APPLICATIONS

This application is a U.S. non-provisional application claiming the benefit of French Application No. 24 13573, filed on Dec. 6, 2024, which is incorporated herein by reference in its entirety.

### FIELD

The present invention relates to maintaining equipment under operational conditions.

### BACKGROUND

The reliability of equipment, especially those including electronic systems, depends significantly on the stress experienced during their operational period, particularly thermal stress, which can lead to failures, latencies, or accelerated aging.

Various solutions are known in the prior art for detecting thermal anomalies from temperature data recorded over time, but these have limitations.

A first solution involves designing an expert system that applies business rules (e.g., “if the card is used in such a context, its temperature must remain between a predefined minimum and maximum value”) defined by business experts, simulations, or feedback analysis. This approach has several drawbacks:
thresholds are set statically, and their adjustment may be disconnected from the real need, or include biases and preconceptions that can lead to false positives (false alarms);
it allows for the detection of strong anomalies, but not necessarily weak signals whose characterization requires more subtle processing than thresholding;
the rules used generally lack flexibility to adapt to different situations that may be encountered in the input data. Their design also requires expert knowledge and is not automated.

A second solution involves statistically analyzing the temperature distributions of equipment over their entire operational periods (typically in the form of a “box plot,” which displays the values usually taken by the temperature and their dispersion), and empirically and self-adjusting the minimum and maximum temperature thresholds. However, the abnormality of a measured temperature depends greatly on the context in which the card is used: if the measured temperature is higher than all past observed measurements, there is not necessarily a need to alert an anomaly if it is explained by atypical and intensive use of the equipment causing it to overheat. This solution thus leads to false positives and conversely to missing minor anomalies in atypical contexts.

A third solution exploits machine learning, whose algorithms can empirically and automatically learn to precisely identify what makes a temperature abnormal by finely linking it to a usage context. This learning is based on historical data. There are several prior-art algorithms dedicated to anomaly detection, such as LOF (“Local Outlier Factor”), which identifies an abnormal data point called an “Outlier” by considering a set of characteristic variables, such as those characterizing the use of the equipment. Again, an anomaly can be identified when the equipment is used atypically (e.g., over a longer period than usual, or at very high altitudes in an aircraft, etc.) and this leads to false positives.

### SUMMARY

The aim of the invention is to propose a reliable and relevant solution for detecting thermal anomalies related to equipment.

To this end, the invention relates to a method for detecting a thermal anomaly of equipment, the method being implemented by an electronic detection device and comprising, during an operational period of the equipment, a step of:
i. collecting the current temperature values T(t) of the equipment at times t during the operational period;
   the method being characterized in that it also comprises, during the operational period of the equipment, the steps of:
ii. based on the current temperature values T(t) collected, calculating T_{eq}(t), named asymptotic equilibrium temperature, towards which the temperature of the equipment tends in the vicinity of t, verifying, by local extrapolation of T(t) in an exponential form:

$$T ( t + Δ t ) = {T}_{e q} ( t ) + [ T ( t ) - {T}_{e q} ( t ) ] \cdot {e}^{- \frac{Δ t}{τ}} ; e ;$$

iii. collecting the values of usage variables, characterizing the use and context of use of the equipment at each instant t, collectively referred to as the vector x_{usage}(t);
iv. providing the usage vectors x_{usage}(t) as input to a prediction block adapted to predict the asymptotic equilibrium temperatures at times t, \hat{T}_{eq}(t), based on the vectors x_{usage}(t);
v. calculating the difference between the calculated and predicted asymptotic temperatures: \hat{ε}(t)=T_{eq}(t)−\hat{T}_{eq}(t) and determining based on at least said difference, the presence of a thermal anomaly of the equipment.

Such a method takes into account the physical behavior of the equipment, particularly the thermal transfer laws that govern the dynamics of temperatures over time. This allows for the detection of minor thermal anomalies and precise correlation of temperatures with the use of the equipment. For example, an electronic card may be hot in a context that heats it little, because its temperature depends on what it has previously undergone and its thermal inertia: properly modeling the thermal dynamics is necessary to best address the issue and limit false positives.

T_{eq} and τ are defined as the parameters of the exponential that best approximates the temperature curve T in the vicinity of t. In one embodiment, their values can be estimated numerically. In one embodiment, it is not necessary to estimate τ, T_{eq}, being approximated directly based on T(t), T′(t), and T″(t) as described below.

According to other advantageous aspects of the invention, the method according to the invention comprises one or more of the following features, taken in isolation or in any technically possible combination:
the method comprises at least one of the following provisions:
the temperature of the equipment is not part of the usage variables,
the usage variables include one or more pieces of information related to the equipment or a system including the equipment, among:
   electrical voltage, position, speed, acceleration, dynamic pressure, operating mode, mission type, meteorological data, calendar data;
at step ii, the asymptotic equilibrium temperature T_{eq}(t) is calculated based on the following formula:

$$T ( t ) - \frac{{( {T}^{′} ( t ) )}^{2}}{{T}^{″} ( t )}$$

Where T′(t) is the first derivative, and T″(t) the second derivative, of T(t);
step ii., the absolute value of T″(t) is compared to a predefined threshold, and if said absolute value of T″(t) is less than the predefined threshold, the data relating to the instant t are discarded from further processing;
at step ii, a median, respectively mean, temporal smoothing is applied to the results provided by the formula

$$T ( t ) - \frac{{( {T}^{′} ( t ) )}^{2}}{{T}^{″} ( t )} ,$$

by a centered sliding window, and T_{eq}(t) is calculated based on the median, respectively the mean, of the results of said formula between

$$t - \frac{L}{2} and t + \frac{L}{2}$$

where L Is the size of the sliding window;
at step v, a thermal anomaly is detected if and only if a parameter based on the difference \hat{ε}(t) is outside a predefined range of values over at least N instants during the operational period, with N set strictly greater than 1;
the prediction block is designed by supervised learning of a machine learning algorithm and using training data including, for the instants t′ of operational periods, usage vectors x_{usage}(t′) and asymptotic equilibrium temperatures, T_{eq}(t′), so that the machine learning algorithm, at the end of the training, delivers as output, with a fixed margin of error, a predicted asymptotic equilibrium temperature value T_{eq}(t′), estimation of T_{eq}(t′), for an input value x_{usage}(t′);
at step v, the determination of the presence of a thermal anomaly of the equipment is performed based on said difference and at least one threshold defined based on the statistical distribution of the deviations between predicted \hat{T}_{eq}(t′) and calculated T_{eq}(t′) asymptotic equilibrium temperatures for the instants t′ of operational periods considered for supervised learning.

The invention also relates to a non-transitory computer-readable medium including a computer program including software instructions which, when executed by a computer, implement a method for detecting a thermal anomaly as defined above.

The invention also relates to a device for detecting a thermal anomaly of equipment, the device being adapted to, during an operational period of the equipment, collect the current temperature values T(t) of the equipment at times t during the operational period;
said device being adapted to, based on the current temperature values T(t) collected, calculate T_{eq}(t), named asymptotic equilibrium temperature, towards which the temperature of the equipment tends in the vicinity of t, verifying, by local extrapolation of T(t) in an exponential form:

$$T ( t + Δ t ) = {T}_{e q} ( t ) + [ T ( t ) - {T}_{e q} ( t ) ] \cdot {e}^{- \frac{Δ t}{τ}} ;$$

said device being adapted to collect the values of usage variables, characterizing the use and context of use of the equipment at each instant t, collectively referred to as the vector x_{usage}(t);
said device including a prediction block adapted to predict the asymptotic equilibrium temperatures at times t, \hat{T}_{eq}(t), based on the vectors x_{usage}(t), said device is adapted to provide the usage vectors x_{usage}(t) as input to said prediction block,
said device being adapted to calculate the difference between the calculated and predicted asymptotic temperatures: \hat{ε}(t)=T_{eq}(t)−\hat{T}_{eq}(t) and to determine based on at least said difference, the presence of a thermal anomaly of the equipment.

### BRIEF DESCRIPTION OF THE DRAWINGS

The invention will become clearer upon reading the following description, given solely by way of non-limiting example, and made with reference to the drawings wherein:

FIG. 1 is a flowchart of the steps of a method in one embodiment of the invention;

FIG. 2 schematically represents a detection device in one embodiment of the invention;

FIG. 3 is a graphical representation illustrating notably the meaning of the asymptotic temperature of equipment at an instant t₀;

FIG. 4 illustrates the interquartile range (IQR) method; and

FIG. 5 is a graph representing the evolution during an operational period of the actual temperature of equipment, the calculated asymptotic equilibrium temperature, and the predicted asymptotic equilibrium temperature.

### DETAILED DESCRIPTION

As an illustration, the equipment of interest here is an electronic card, which is part of an operational system, here, for example, a radar, embedded in a carrier type aircraft.

Of course, the invention can be implemented on any type of equipment, with or without a carrier, with or without a system. The thermal heating considered can be due to various causes (Joule effect, friction, conditioning failure, external disturbances, etc.).

In an operational situation, the equipment is put into service for a certain period of time called the “operational period.” In the present case, the card is turned on, i.e., continuously powered during an operational period corresponding here, for example, to a flight of the aircraft, or at least part of a flight.

The invention applies to cases where data is collected relative to one or more pieces of equipment in the operational phase, in order to monitor in real-time the behavior of the equipment and its use during each operational period. Such data measures, for example, values from physical sensors (temperatures, voltages, humidity, etc.) embedded on the equipment, on the system, as well as usage and operational context data (position, altitude, speed of the carrier, equipment settings, commands used, etc.). The industrial processes allowing their collection and exploitation are generally known as “HUMS” (Health and Usage Monitoring Systems). Of course, these data are adapted according to the context.

During a considered operational period, data is collected and recorded over time t, in the form of time series (values evolving over time according to a certain sampling period, for example, one value every second). These data include:
the actual temperature of the equipment at instant t, noted T(t), for example, provided as output from a thermal sensor positioned on the electrical card and measuring this actual temperature of the card;
values, at instant t (for example directly or indirectly from sensors other than thermal), characterizing the use of the equipment, the context of use of the system, and potentially impacting the temperature of the equipment. These values must provide information about how the equipment is used or stressed. For example, for a card in an airborne radar, they include, for example, all or part of the following information: electrical voltages, humidity, the altitude of the aircraft, its speed, its acceleration, dynamic pressure, the emission state of the system, its modes and activated parameters, mission types, and meteorological, geographical, or calendar data, etc. All these values at instant t are the respective components of a vector x_{usage}(t).

The method presupposes that the use made of the equipment determines at least to some extent the measured temperature, and that this can therefore be expressed in the form:

$$T ( t ) ≃ F ( {x}_{usage} ( t ) ) + ε ( t ) \qquad ( 1 )$$

where the temperature T varies according to the use of the equipment (this use is characterized by the vector x_{usage}) according to an unknown function F, and ε corresponds to a stochastic residue not deductible from the recorded data, such as exogenous factors impacting the temperature but not recorded in the collected data, or even the random thermal noise of the thermal sensor.

To assess whether a measured temperature is abnormal during an operational period, the idea is to subtract from it the contribution explained by the use, quantified empirically by a supervised machine learning algorithm that has undergone prior learning, and, in a second step, to estimate whether the result of the difference (the residue) is normal, for example, by comparing it to the values usually found in the data history using statistical methods.

But to take into account the thermal dynamics of the card, the temperature varying with a certain inertia, and the temperature at an instant t not depending solely on its current use, but also on what the card has undergone at previous instants (for example, the card may be very hot in a context where it is cooled if it has previously been strongly heated), it is proposed, according to the invention, to replace the temperature with the notion of asymptotic temperature, whose definition and calculation method are given below. Intuitively: this allows how the current use of the card influences, not the current temperature, but the equilibrium temperature towards which it tends to be studied. The residue ε then measures the gap between the observed thermal equilibrium and that explained by the use, allowing for unexplained heating/cooling by the use to be accounted for. If the value of the residue is significant (or if this is confirmed throughout the operational period), the presence of a thermal anomaly is detected.

### Exposition of the Principles Underlying the Invention:

The temperature T(t) of the electronic card, as measured by the thermal sensor, varies over time according to the thermal fluxes it undergoes, and which characterize the thermodynamic context of the card.

By summing these fluxes and applying the law of cooling conceived by Newton, a relation of the type is obtained:

$$C \frac{d T}{d t} = - λ ( T - {T}_{e x t} ) + {ϕ}_{i n t} + {ϕ}_{e x t} \qquad ( 2 )$$

where C and λ are physical parameters representing the thermal capacity and conductivity of the card; Tₑₓₜ corresponds to the temperature of the air surrounding the card for cooling, linked to the conditioning used. The term −λ(T−Tₑₓₜ) corresponds to the convective heat flux of the cooling by air of the card, φᵢₙₜ represents the internal heat flux generated by the card by Joule effect, and φₑₓₜ groups any remaining external fluxes to the card (friction, influence of surrounding materials, etc.).

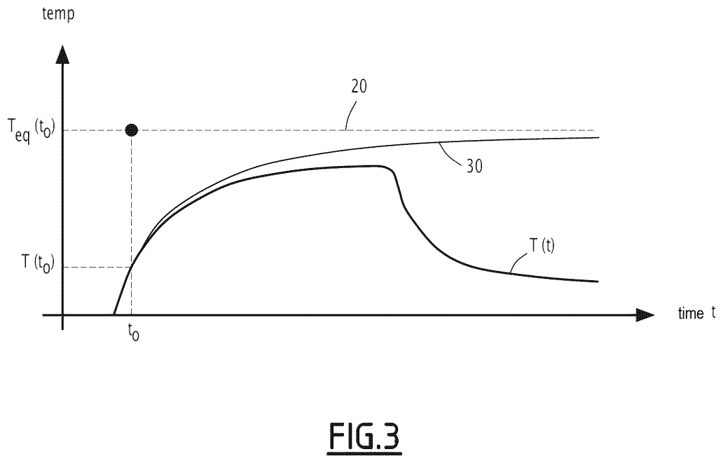

Referring to FIG. 3, which notably represents the actual temperature T(t) of the card at instant t, if we consider an instant t₀: by reasoning locally in the vicinity of t₀ over a sufficiently small time interval Δt, it is possible to neglect the variations of the thermodynamic context of the card and to consider by continuity that the parameters of equation (2) above remain constant. A first-order linear differential equation is then classically obtained, whose solution evolves according to a convergent exponential:

$$T ( {t}_{0} + Δ t ) = {T}_{e q} ( {t}_{0} ) + [ T ( {t}_{0} ) - {T}_{e q} ( {t}_{0} ) ] \cdot {e}^{- \frac{Δ t}{τ}} \qquad ( 3 )$$

where T_{eq}(t₀) is the asymptotic equilibrium temperature (line 20) towards which the temperature T of the card seems to tend in the vicinity of t₀, and

$$τ = \frac{c}{λ}$$

is a time constant characterizing the thermal inertia of the card.

Thus, it follows from the above that, locally in the vicinity of to, the temperature evolves according to an exponential which, once extrapolated (curve 30), tends towards the asymptotic temperature T_{eq}(t₀).

In one embodiment, T_{eq} and τ are numerically estimated as the parameters of the exponential that best approximates the temperature curve T(t) in the vicinity of t₀.

In one embodiment, τ is not even calculated: it disappears when transitioning from equations 4 and 5 to equation 6, as now described.

To numerically estimate this asymptotic temperature, it is possible to calculate the first and second derivatives of T in its exponential form (3), evaluated at t₀:

$${T}^{′} ( {t}_{0} ) = - \frac{1}{τ} [ T ( {t}_{0} ) - {T}_{e q} ( {t}_{0} ) ] \qquad ( 4 )$$

$${T}^{′′} ( {t}_{0} ) = \frac{1}{{τ}^{2}} [ T ( {t}_{0} ) - {T}_{e q} ( {t}_{0} ) ] \qquad ( 5 )$$

By isolating T_{eq}(t₀) from equations (4) and (5), the following formula is deduced:

$${T}_{e q} ( {t}_{0} ) = T ( {t}_{0} ) - \frac{{( {T}^{′} ( {t}_{0} ) )}^{2}}{{T}^{′′} ( {t}_{0} )}$$

Thus, more generally at each instant t, the asymptotic temperature T_{eq}(t) towards which the card tends asymptotically in the vicinity of t can be calculated according to the following formula:

$${T}_{e q} ( t ) = T ( t ) - \frac{{( {T}^{′} ( t ) )}^{2}}{{T}^{′′} ( t )} \qquad ( 6 )$$

The values of T′(t) and T″(t) can be calculated by classical numerical methods, such as formulas (7) and (8):

$${T}^{′} ( t ) = \frac{T ( t + h ) - T ( t - h )}{2 h} \qquad ( 7 )$$

$${T}^{″} ( t ) = \frac{T ( t + h ) + T ( t - h ) - 2 T ( t )}{{h}^{2}} \qquad ( 8 )$$

where the step h taken as small as possible is minimized by the sampling period of the temperature sensor.

In practice, the actual temperatures measured by the temperature sensor are noisy. This noise, depending on its amplitude, can strongly disturb the above calculations. In one embodiment, techniques are applied to attenuate these effects.

For example, classically in formulas (7) and (8), the choice of step h can be adjusted to further smooth the noise.

The formula for the asymptotic temperature (6) presents strong instabilities when the temperature evolves linearly (because in this case T″(t) tends towards 0, and the denominator of formula (6) diverges.) This is amplified in the presence of noise in the temperature data.

To correct these instabilities, in one embodiment, a median smoothing is applied to the previously calculated asymptotic temperature over a centered sliding time window.

Thus, each value of T_{eq}(t) is replaced by the median of the value of T_{eq} between

$$t - \frac{L}{2} and t + \frac{L}{2}$$

where L is the size of the sliding window, to be adjusted according to the noise present in the signal. The mean could be chosen instead of the median, but the choice of the median rather than the mean allows for better robustness.

In one embodiment, the calculated values of T_{eq} when the denominator T″(t) approaches too close to 0 (comparison of the absolute value of T″(t) to a predefined threshold) are censored.

These techniques allow for the encountered instabilities to be effectively corrected.

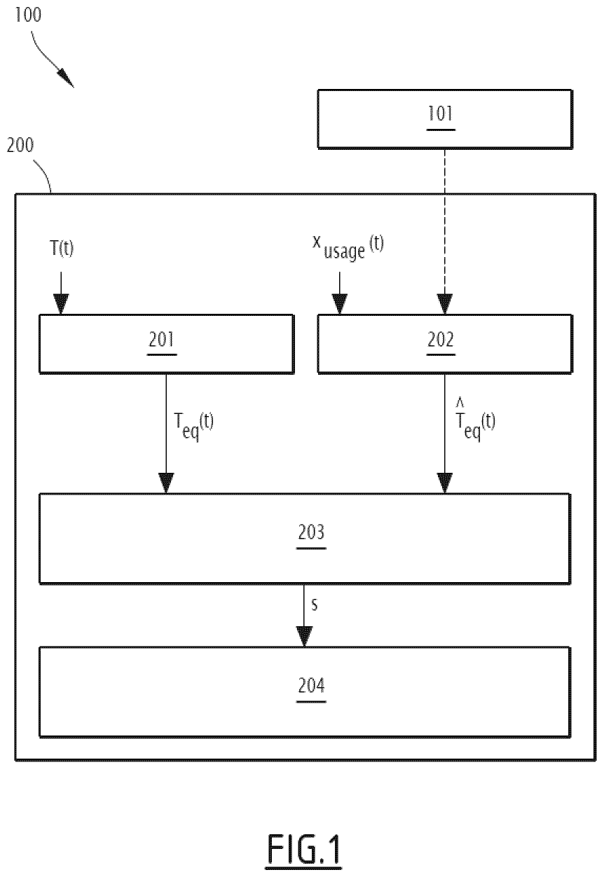

FIG. 1 indicates, in one embodiment, the steps of a method 100 for detecting a thermal anomaly of equipment, in the considered example an electronic card of an airborne radar.

In a preliminary step 101, an algorithmic tool is first designed to, at each instant t, receive as input the usage data x_{usage}(t) and to deliver as output the corresponding predicted asymptotic temperature based on these usage data, named \hat{T}_{eq}(t). This tool, which models the link between usage and the asymptotic temperature of the card, is named block 12 of asymptotic temperature prediction. It is obtained by machine learning, typically by training an artificial neural network.

For example, a supervised learning algorithm of the regression type is used, such as “multilayer perceptron” or others.

It is recalled here that a neural network comprises an ordered succession of layers of neurons, each taking its inputs from the outputs of the previous layer.

More precisely, each layer comprises neurons taking their inputs from the outputs of the neurons of the previous layer, or from the input variables for the first layer.

Alternatively, more complex neural network structures can be considered with a layer that can be connected to a layer further away than the immediately preceding layer.

Each neuron is also associated with an operation, i.e., a type of processing, to be performed by said neuron within the corresponding processing layer.

Each layer is connected to the other layers by a plurality of synapses. A synaptic weight is associated with each synapse, and each synapse forms a connection between two neurons. It is often a real number, which can take positive or negative values. In some cases, the synaptic weight is a complex number.

Each neuron is capable of performing a weighted sum of the value(s) received from the neurons of the previous layer, each value being then multiplied by the respective synaptic weight of each synapse, or connection, between said neuron and the neurons of the previous layer, then applying an activation function, typically a non-linear function, to said weighted sum, and delivering as output from said neuron, in particular to the neurons of the next layer to which it is connected, the value resulting from the application of the activation function. The activation function allows non-linearity to be introduced into the processing performed by each neuron. The sigmoid function, the hyperbolic tangent function, and the Heaviside function are examples of activation functions.

Optionally, each neuron is also capable of applying, in addition, a multiplicative factor, also called bias, to the output of the activation function, and the value delivered as output from said neuron is then the product of the bias value and the value resulting from the activation function.

Learning is a phase, implemented for example by a learning algorithm, running on a computer processor, allowing the values of the parameters of the neural network to be set, notably the synapse weights, as well as the biases and activation function; it is said to be supervised when the network is forced to converge towards a precise final state, at the same time as a pattern is presented to it

The neural network is thus trained from learning data stored in a historical data table, corresponding to several past operational periods of the card allowing the average and usual thermal behavior to be translated. In this table, each row/sample corresponds to an instant t of one of these operational periods. In a sample, the following are provided: the actual temperature measured at instant t, the corresponding asymptotic temperature calculated, for example, from the actual temperature using formula 6 (and, for example, also smoothed by a median smoothing as indicated above, and the rows corresponding to a T″(t) too close to zero having been removed), as well as the values of the usage variables at instant t, grouped in the vector x_{usage}(t).

The target variable (variable that the neural network is trained to predict) is the asymptotic temperature.

The neural network takes as input for each instant t, the usage variables (for example here, as indicated above: the altitude of the carrier, its speed, the emission state, the radar mode used, etc.), and is trained to predict towards which asymptotic temperature the card tends knowing its current usage. The function implemented by the network corresponds to a parametric function \hat{F}_{ω} whose learning consists of optimizing its parameters ω (typically the synaptic coefficients of the neural network) to minimize the error made between the result delivered by the neural network and the target variable. The error used is the RMSE (Root Mean Square Error), which calculates the standard deviation of the deviations between predicted asymptotic temperatures T_{eq}(t)) and calculated ones. Once trained at the end of step 101, the prediction block 12 is adapted to estimate giving the most probable asymptotic temperature knowing a given usage:

$${\hat{T}}_{e q} ( t ) = {\hat{F}}_{ω} ( {x}_{usage} ( t ) ) \qquad ( 9 )$$

Once trained, the prediction block 12 is evaluated on a part of the historical database reserved for evaluation. This allows the accuracy of the estimator to be quantified, and the margin of error of the prediction to be estimated, and the learning to be extended until the margin of error is below a predefined error threshold.

For example, in one embodiment, the RMSE obtained is less than or equal to 5° C.

The neural network-based model giving rise to the prediction block 12 is, for example, implemented using a programming language (for example, Python, Java, C++, etc.) with libraries for data processing and training of machine learning algorithms (for example, Pandas and Scikit-Learn in Python).

It can be developed and trained on a platform hosting a historical database recorded during past operational periods of the card. The computing power required depends on the size of the data used.

Once trained, the prediction block 12 is obtained by deploying the model on a dedicated support allowing the new data received during a use of the equipment to be analyzed.

Once this preliminary learning step 101 is completed, the set 200 of thermal anomaly detection steps is implemented by the thermal anomaly detection device 10 during operational periods of the card.

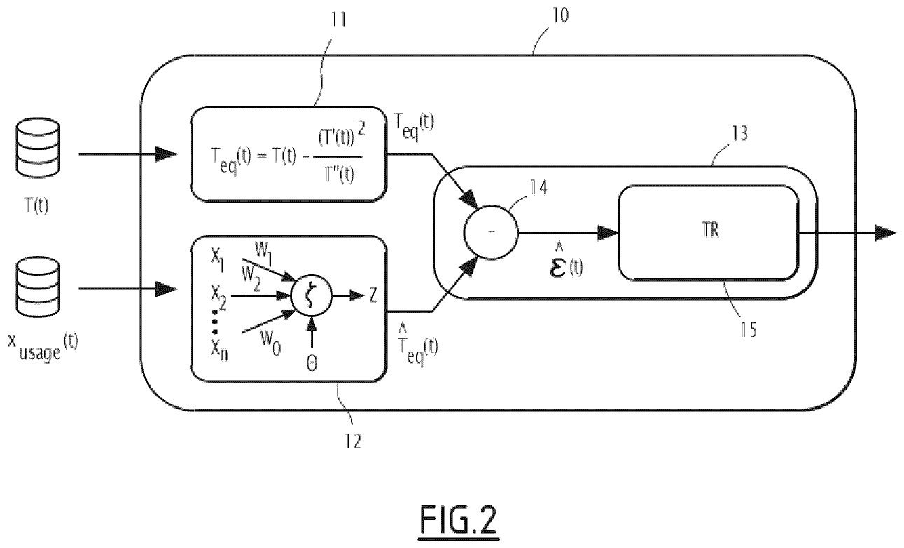

In the considered embodiment, the thermal anomaly detection device 10 comprises, with reference to FIG. 2, a block 11 for calculating the asymptotic equilibrium temperature T_{eq}(t), the prediction block 12 of the asymptotic equilibrium temperature \hat{T}_{eq}(t) resulting from step 101, and a processing block 13.

The set of steps 200 implemented at each detection instant t (for example every second) during an operational period is now described more precisely.

The thermal anomaly detection device 10 receives as input the temperature data T(t) and usage data x_{usage}(t) over time, and is adapted to determine whether a thermal anomaly affecting the card is present or not.

In a step 201, the block 11 for calculating the asymptotic equilibrium temperature calculates the asymptotic temperature T_{eq}(t). based on the temperature T(t) of the card at instant t. For this, in one embodiment, it determines the solution of equation (3). In one embodiment, for this, it calculates, by classical numerical methods, the first T′(t) and second T″(t) derivatives of T(t) and deduces

$$T ( t ) - \frac{{( {T}^{′} ( t ) )}^{2}}{{T}^{″} ( t )} . \qquad ( cf . equation 6 )$$

In one embodiment, to correct noise and numerical instabilities, the block 11 then applies a median temporal smoothing by a centered sliding window on t as described above and/or identifies the values T″(t) too close to zero and triggers their exclusion from the anomaly detection process. The asymptotic temperature T_{eq}(t) calculated by block 11 is provided as input to processing block 13.

In a step 202, which takes place for example in parallel with step 201, the prediction block 12 predicts, based on the usage vector x_{usage}(t), the predicted asymptotic temperature:

$${\hat{T}}_{e q} ( t ) = {\hat{F}}_{ω} ( {x}_{usage} ( t ) ) .$$

The asymptotic temperature \hat{T}_{eq}(t) predicted by block 12 is provided as input to processing block 13.

In a step 203, following receipt of the calculated T_{eq}(t) and predicted T_{eq}(t) asymptotic temperatures for instant t, processing block 13 calculates the difference between these two values, using a subtractor 14. The residue \hat{ε}(t), result of this difference, represents what is not explained by the use of the card:

$$\hat{ε} ( t ) = {T}_{e q} ( t ) - {\hat{F}}_{ω} ( {x}_{usage} ( t ) ) \qquad ( 10 )$$

The TR sub-block 15 of processing block 13 then determines, based on at least the value of this residue \hat{ε}(t), the detection result s (t) indicating whether or not a thermal anomaly of the card is detected for the detection instant t.

This determination is, for example, performed by comparing the residue \hat{ε}(t) (or a parameter determined based on the residue) to a predefined threshold.

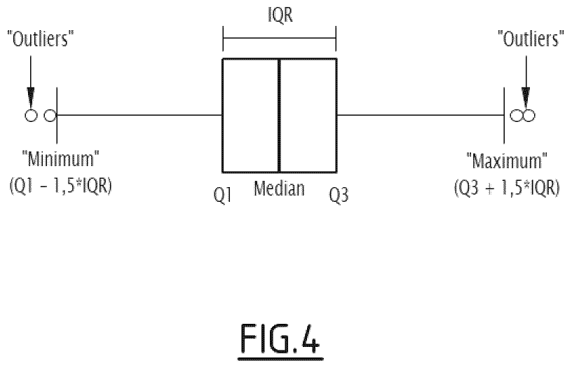

In one embodiment, a minimum threshold value and/or a maximum threshold value for the residue are predefined, for example, at the end of preliminary step 101, by calculating the residues relative to the historical samples and analyzing the distribution of the obtained residue values, in order to identify minimum and maximum thresholds from which the values are considered extreme or abnormal (so-called “outlier” values). Several statistical methods allow this to be done automatically, for example, the interquartile range (IQR) method, schematically illustrated in FIG. 4: the minimum threshold is set equal to Q1−1.5*IQR, the maximum threshold is set equal to Q3+1.5*IQR, where IQR is the difference between the Q1 (25^{th} percentile of the distribution) and Q3 (75^{th} percentile of the distribution) values.

When the obtained residue is beyond the range defined by these thresholds, its value is significant relative to the margin of error of prediction block 12.

In one embodiment, an additional safeguard is, for example, then applied by TR sub-block 15, when an anomaly has been detected at a considered instant t: it is evaluated whether this threshold exceedance is confirmed in a prolonged manner over a determined subset or the entire instants of the studied operational period. TR sub-block 15 triggers an alert for a thermal anomaly if and only if the residue is outside the allowed range on more than X % (for example, 80%) of the instants of the operational period. These prolonged exceedances may indicate abnormal heating, a conditioning problem, or even atypical behavior of the card.

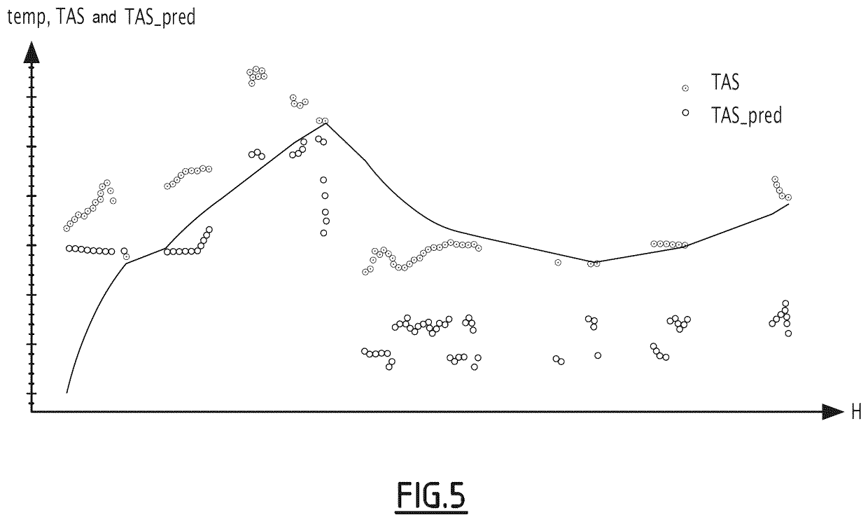

As an illustration, the graph in FIG. 5 has the hours of the operational period (a flight) on the abscissa and the temperature indication on the ordinate. The thin continuous line is the actual temperature measured by the temperature sensor, the TAS curve indicates the asymptotic temperature values calculated by block 11, the TAS_pred curve indicates the asymptotic temperature values predicted by block 12: this case is that of an atypical flight where abnormal heating is confirmed over the entire flight, with a significant gap between the measured and expected values. An alert indicating the presence of a thermal anomaly is then sent in this case by processing block 13.

In a step 204, the result of the thermal anomaly detection (indicating the presence or absence of an anomaly for instant t as well as optional complementary information, such as the value of \hat{ε}(t), etc.) provided by TR sub-block 15 is exploited, for example, by processing block 13 or by another electronic module, in order to:
schedule maintenance operations—or even component replacements—of the equipment,
anticipate failures,
comparatively evaluate the health status of the equipment to recommend the most reliable ones in critical operational contexts where a failure can have adverse impacts,
understand the origin of certain failures, and feed predictive failure models.

The invention thus proposes a solution allowing alerting in case of thermal anomalies of monitored equipment over time, including the following advantages:
the prediction model is self-trained from historical data, by means of a supervised learning algorithm, whose temperature prediction performances can be empirically measured;
the model allows the use of the equipment to be taken into account by modeling its impact on the temperature of the equipment, to detect minor thermal anomalies and limit false positives related to atypical uses;
the notion of asymptotic temperature allows the thermal dynamics of the card to be taken into account and better modeling of the impact of use by studying how the latter influences the thermal equilibrium towards which the temperature tends;
the model allows minor thermal anomalies not visible to the naked eye to be detected by an expert investigating the data manually.

The invention can be applied in any type of industrial process where equipment, for example, electronic, is monitored over time, with recording of temperature and usage data. It is useful in cases where there is a need to be alerted in case of abnormal equipment behavior, particularly in case of overheating that can degrade the performance and reliability of the equipment.

In one embodiment, detection device 10 comprises a calculator and a memory (not shown), the memory storing software instructions which, when executed on the calculator, implement at least some steps of the set of steps 200.

When the method is thus implemented in the form of one or more software, i.e., in the form of a computer program, also called a computer program product, it is also capable of being recorded on a medium (not shown), which can be read by a computer. The computer-readable medium is, for example, a medium capable of storing electronic instructions and being coupled to a bus of a computer system. For example, the readable medium is an optical disk, a magneto-optical disk, a ROM memory, a RAM memory, any type of non-volatile memory (for example, FLASH or NVRAM), or a magnetic card. On the readable medium is then stored a computer program including software instructions.

In another embodiment, at least some of the functions of detection device 10 are implemented by a programmable logic component, such as an FPGA (Field Programmable Gate Array), or an integrated circuit, such as an ASIC (Application Specific Integrated Circuit).

1. A method for automatically detecting a thermal anomaly of equipment, the method being implemented by an electronic detection device and comprising during an operational period of the equipment:
i. collecting the current temperature values T(t) of the equipment at times t during the operational period;
wherein the method further comprises, during the operational period of the equipment:
ii. based on the current temperature values T(t) collected, calculating T_{eq}(t), named asymptotic equilibrium temperature, towards which the temperature of the equipment tends in the vicinity of t, verifying, by local extrapolation of T(t) in an exponential form:
$$T ( t + Δ t ) = {T}_{e q} ( t ) + [ T ( t ) - {T}_{e q} ( t ) ] \cdot {e}^{- \frac{Δ t}{τ}} ;$$
and
iii. collecting the values of usage variables, characterizing the use and context of use of the equipment at each instant t, collectively referred to as the vector x_{usage}(t);
iv. providing the usage vectors x_{usage}(t); as input to a prediction block adapted to predict the asymptotic equilibrium temperatures at times t, \hat{T}_{eq}(t), based on the vectors x_{usage}(t);
v. calculating the difference between the calculated and predicted asymptotic temperatures: \hat{ε}(t)=T_{eq}(t)−\hat{T}_{eq}(t) and determining based on at least said difference, the presence of a thermal anomaly of the equipment.

2. The method according to claim 1, comprising at least one of the following provisions:
the temperature of the equipment is not part of the usage variables,
the usage variables include one or more pieces of information related to the equipment or a system including the equipment, among:
electrical voltage, position, speed, acceleration, dynamic pressure, operating mode, mission type, meteorological data, calendar data.

3. The method according to claim 1, wherein at step ii, the asymptotic equilibrium temperature T_{eq}(t) is calculated based on the following formula:
$$T ( t ) - \frac{{( {T}^{′} ( t ) )}^{2}}{{T}^{″} ( t )}$$
where T′(t) is the first derivative, and T″(t) the second derivative, of T(t).

4. The method according to claim 3, wherein at step ii., the absolute value of T″(t) is compared to a predefined threshold, and if said absolute value of T″(t) is less than the predefined threshold, the data relating to the instant t are discarded from further processing.

5. The method according to claim 3, wherein at step ii, a median, respectively mean, temporal smoothing is applied to the results provided by the formula
$$T ( t ) - \frac{{( {T}^{′} ( t ) )}^{2}}{{T}^{″} ( t )} ,$$
by a centered sliding window, and T_{eq}(t)) is calculated based on the median, respectively the mean, of the results of said formula between
$$t - \frac{L}{2} and t + \frac{L}{2}$$
where L is the size of the sliding window.

6. The method according to claim 1, wherein at step v, a thermal anomaly is detected if and only if a parameter based on the difference \hat{ε}(t) is outside a predefined range of values over at least N instants during the operational period, with N set strictly greater than 1.

7. The method according to claim 1, wherein the prediction block is designed by supervised learning of a machine learning algorithm and using training data including, for the instants t′ of operational periods, usage vectors x_{usage}(t′) and asymptotic equilibrium temperatures, T_{eq}(t′), so that the machine learning algorithm, at the end of the learning, delivers as output, with a fixed margin of error, a predicted asymptotic equilibrium temperature value T_{eq}(t′), estimation of T_{eq}(t′), for an input value x_{usage}(t′).

8. The method according to claim 7, wherein at step v, the determination of the presence of a thermal anomaly of the equipment is performed based on said difference and at least one threshold defined based on the statistical distribution of the deviations between predicted T_{eq}(t′) and calculated T_{eq}(t′) asymptotic equilibrium temperatures for the instants t′ of operational periods considered for supervised learning.

9. A non-transitory computer-readable medium including a computer program including software instructions which, when executed by a computer, implement a method for detecting a thermal anomaly according to claim 1.

10. A device for automatically detecting a thermal anomaly of equipment, the device being adapted to, during an operational period of the equipment, collect the current temperature values T(t) of the equipment at times t during the operational period;
said device being adapted to, based on the current temperature values T(t) collected, calculate T_{eq}(t), named asymptotic equilibrium temperature, towards which the temperature of the equipment tends in the vicinity of t, verifying, by local extrapolation of T(t) in an exponential form:
$$T ( t + Δ t ) = {T}_{e q} ( t ) + [ T ( t ) - {T}_{e q} ( t ) ] \cdot {e}^{- \frac{Δ t}{τ}} ;$$
said device being adapted to collect the values of usage variables, characterizing the use and context of use of the equipment at each instant t, collectively referred to as the vector x_{usage}(t);
said device including a prediction block, said device is adapted to provide the usage vectors x_{usage}(t) as input to said prediction block adapted to predict the asymptotic equilibrium temperatures at times t, \hat{T}_{eq}(t), based on said vectors x_{usage}(t);
said device being adapted to calculate the difference between the calculated and predicted asymptotic temperatures: \hat{ε}(t)=T_{eq}(t)−\hat{T}_{eq}(t) and to determine based on at least said difference, the presence of a thermal anomaly of the equipment.
